(19) United States
(12) Patent Application Publication
(10) Pub. No.: US 2020/0152569 A1
(43) Pub. Date: May 14, 2020

(54) FAN-OUT SEMICONDUCTOR PACKAGE

(71) Applicant: SAMSUNG ELECTRONICS CO., LTD., Suwon-si (KR)

(72) Inventors: Jeongho Lee, Suwon-si (KR); Hoyeon Jo, Suwon-si (KR); Shanghoon Seo, Suwon-si (KR); Younggwan Ko, Suwon-si (KR); Sangkyu Lee, Suwon-si (KR)

(73) Assignee: SAMSUNG ELECTRONICS CO., LTD., Suwon-si (KR)

(21) Appl. No.: 16/580,156

(22) Filed: Sep. 24, 2019

(30) Foreign Application Priority Data
Nov. 13, 2018 (KR) 10-2018-0139168

(51) Int. Cl. H01L 23/522; H01L 23/00; H01L 23/528; H01L 23/31

(52) U.S. Cl. CPC H01L 23/5226; H01L 24/17; H01L 24/09; H01L 23/5283; H01L 23/3171; H01L 23/3128; H01L 2924/3511; H01L 2224/02373; H01L 2224/02377; H01L 2224/02379; H01L 2224/02381; H01L 2224/0401; H01L 23/5286

(57) ABSTRACT

A fan-out semiconductor package includes a frame having a recess portion, and a semiconductor chip having an active surface on which a connection pad is disposed and an inactive surface opposing the active surface, the semiconductor chip being disposed in the recess portion. One or more through-grooves are disposed around the recess portion and each penetrate through at least a portion of the frame to each extend in a respective direction along a respective side surface of the semiconductor chip. A metal layer is disposed on side walls of the one or more through-grooves, and an encapsulant covers at least a portion of each of the frame and the semiconductor chip and fills at least a portion of the recess portion. A connection structure is disposed on the frame and the active surface of the semiconductor chip, and includes a redistribution layer electrically connected to the connection pad.

### CROSS-REFERENCE TO RELATED APPLICATION(S)

This application claims the benefit under 35 USC 119(a) of Korean Patent Application No. 10-2018-0139168 filed on Nov. 13, 2018 in the Korean Intellectual Property Office, the entire disclosure of which is incorporated herein by reference for all purposes.

### BACKGROUND

The present disclosure relates to a semiconductor package, and more particularly, to a fan-out semiconductor package in which an electrical connection structure may be extended, in addition to an area in which a semiconductor chip is disposed.

A major trend in the development of technology related to semiconductor chips is the reduction in the size of components. Therefore, in the package field, it is common to implement a large number of pins with miniaturization in response to a surge in demand for miniaturized semiconductor chips and the like. The semiconductor package technology proposed to meet this requirement is a fan-out semiconductor package. In the case of the fan-out semiconductor package, an electrical connection structure may be redistributed in an area outside of an area in which a semiconductor chip is disposed, thereby implementing a large number of pins while implementing miniaturization.

On the other hand, as the semiconductor package is made to be smaller and thinner, users demand that the thin devices provide high-end performance for user comfort and design considerations. However, electromagnetic waves generated from these components interfere with each other within the confined packages, and malfunction problems may therefore begin to worsen. To prevent the occurrence of such problems, attempts to more actively use electromagnetic interference (EMI) shielding technology have been undertaken.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

An aspect of the present disclosure is to provide a fan-out semiconductor package having an excellent heat radiation effect while having an excellent electromagnetic wave shielding effect.

According to an aspect of the present disclosure, a through-groove in the form of a trench is formed around a recess portion in which a semiconductor chip of a frame is disposed, and a metal layer is formed on a side wall of the through-groove, thereby shielding electromagnetic waves.

According to an aspect of the present disclosure, a fan-out semiconductor package includes a frame having a recess portion, a semiconductor chip having an active surface on which a connection pad is disposed and an inactive surface opposing the active surface, the semiconductor chip being disposed in the recess portion, one or more through-grooves disposed around the recess portion and each penetrating through at least a portion of the frame to each extend in a respective direction along a respective side surface of the semiconductor chip. A metal layer is disposed on side walls of the one or more through-grooves, an encapsulant covers at least a portion of each of the frame and the semiconductor chip and fills at least a portion of the recess portion, and a connection structure is disposed on the frame and the active surface of the semiconductor chip, and includes a redistribution layer electrically connected to the connection pad.

According to an aspect of the present disclosure, a fan-out semiconductor package includes a frame having a recess portion, the frame including first and second wiring layers disposed on different levels, one or more wiring vias electrically connecting the first and second wiring layers to each other, and one or more shielding members disposed around the recess portion and each extending in a respective direction along a periphery of the recess portion. A semiconductor chip has a connection pad and is disposed in the recess portion, an encapsulant covers at least a portion of each of the frame and the semiconductor chip, and fills at least a portion of the recess portion, and a connection structure is disposed on the frame and the semiconductor chip, and includes a redistribution layer electrically connected to the first and second wiring layers and the connection pad. The one or more wiring vias each have a form in which a respective through-hole penetrating through at least a portion of the frame is filled with a metal material. Each of the one or more shielding members has a form in which a metal material is disposed conformally in a respective through-groove penetrating through at least a portion of the frame in the form of a trench.

According to another aspect of the present disclosure, a fan-out semiconductor package includes a frame having a recess portion, a semiconductor chip disposed in the recess portion, and a plurality of through-grooves each penetrating through at least a portion of the frame and disposed around the recess portion such that a through-groove extends along each respective side surface of the recess portion and has a length longer than the respective side surface. A plurality of metal layers are each disposed on side walls of a respective through-groove of the plurality of through-grooves, and an encapsulant covers at least a portion of each of the frame and the semiconductor chip and fills at least a portion of the recess portion.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram illustrating an example of an electronic device system;

FIG. 2 is a schematic perspective view illustrating an example of an electronic device;

FIGS. 3A and 3B are schematic cross-sectional views illustrating a fan-in semiconductor package before and after being packaged;

FIG. 4 shows schematic cross-sectional views illustrating a packaging process of a fan-in semiconductor package;

FIG. 5 is a schematic cross-sectional view illustrating a fan-in semiconductor package mounted on a printed circuit board and ultimately mounted on a mainboard of an electronic device;

FIG. 6 is a schematic cross-sectional view illustrating a fan-in semiconductor package embedded in a printed circuit board and ultimately mounted on a mainboard of an electronic device;

FIG. 7 is a schematic cross-sectional view illustrating a fan-out semiconductor package;

FIG. 8 is a schematic cross-sectional view illustrating a fan-out semiconductor package mounted on a mainboard of an electronic device;

FIG. 9 is a cross-sectional view schematically illustrating an example of a fan-out semiconductor package;

FIG. 10 is a schematic cross-sectional plan view of the fan-out semiconductor package of FIG. 9; and

FIGS. 11A, 11B, 12A, 12B, 13A, 13B, 14A, and 14B are schematic views illustrating a process of manufacturing a frame of the fan-out semiconductor package of FIG. 9.

### DETAILED DESCRIPTION

Hereinafter, examples of the present disclosure will be described with reference to the accompanying drawings. The shape and size of constituent elements in the drawings may be exaggerated or reduced for clarity.

Electronic Device

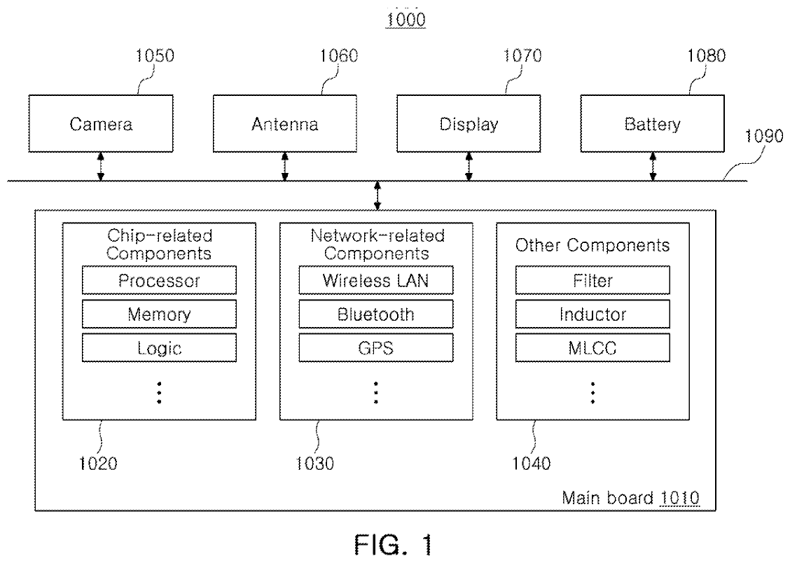

FIG. 1 is a schematic block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related components. In addition, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 or the network related components 1030 described above.

Depending on a type of the electronic device 1000, the electronic device 1000 may include other components that may or may not be physically or electrically connected to the mainboard 1010. These other components may include, for example, a camera module 1050, an antenna 1060, a display device 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

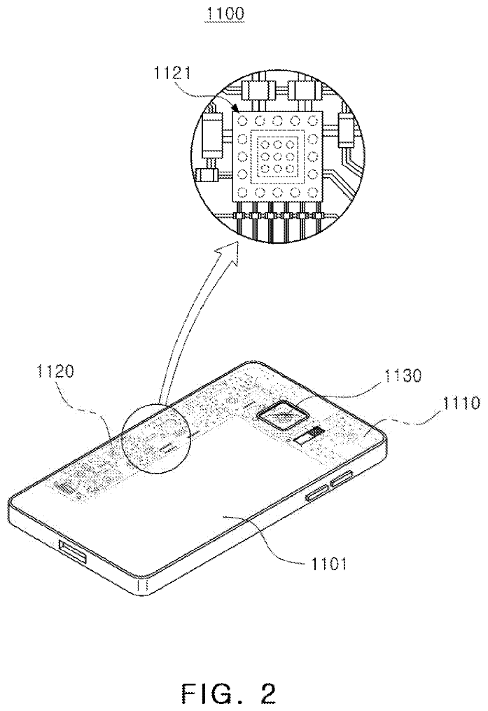

FIG. 2 is a schematic perspective view illustrating an example of an electronic device.

Referring to FIG. 2, a semiconductor package may be used for various purposes in the various electronic devices 1000 as described above. For example, a motherboard 1110 may be accommodated in a body 1101 of a smartphone 1100, and various electronic components 1120 may be physically or electrically connected to the motherboard 1110. In addition, other components that may or may not be physically or electrically connected to the motherboard 1110, such as a camera module 1130, may be accommodated in the body 1101. Some of the electronic components 1120 may be the chip related components, for example, a semiconductor package 1121, but are not limited thereto. The electronic device is not necessarily limited to the smartphone 1100, but may be other electronic devices as described above.

Semiconductor Package

Generally, numerous fine electrical circuits are integrated in a semiconductor chip. However, the semiconductor chip may not serve as a finished semiconductor product in itself, and may be damaged due to external physical or chemical impacts. Therefore, the semiconductor chip itself may not be used, but may be packaged and used in an electronic device, or the like, in a packaged state.

In this case, semiconductor packaging is used due to the existence of a difference in a circuit width between the semiconductor chip and a mainboard of the electronic device in terms of electrical connections. In detail, a size of connection pads of the semiconductor chip and an interval between the connection pads of the semiconductor chip are very fine, but a size of component mounting pads of the mainboard used in the electronic device and an interval between the component mounting pads of the mainboard are significantly larger than those of the semiconductor chip. Therefore, it may be difficult to directly mount the semiconductor chip on the mainboard, and packaging technology for buffering a difference in a circuit width between the semiconductor chip and the mainboard is used.

A semiconductor package manufactured by the packaging technology may be classified as a fan-in semiconductor package or a fan-out semiconductor package depending on a structure and a purpose thereof.

The fan-in semiconductor package and the fan-out semiconductor package will hereinafter be described in more detail with reference to the drawings.

Fan-in Semiconductor Package

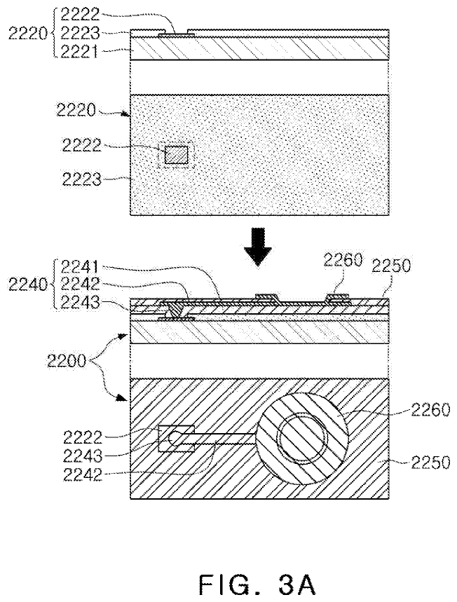

FIGS. 3A and 3B are schematic cross-sectional views illustrating states of a fan-in semiconductor package before and after being packaged.

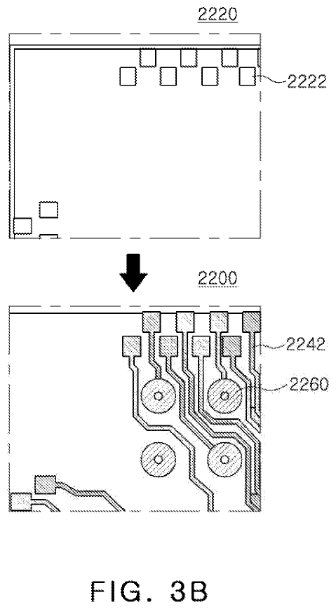

FIG. 4 is schematic cross-sectional views illustrating a packaging process of a fan-in semiconductor package.

Referring to FIGS. 3A to 4, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide layer, a nitride layer, or the like, formed on one surface of the body 2221 and covering at least portions of the connection pads 2222. In this case, since the connection pads 2222 may be significantly small, it may be difficult to mount the integrated circuit (IC) on an intermediate level printed circuit board (PCB) as well as on the mainboard of the electronic device, or the like.

Therefore, a connection member 2240 may be formed depending on a size of the semiconductor chip 2220 on the semiconductor chip 2220 to redistribute the connection pads 2222. The connection member 2240 may be formed by forming an insulating layer 2241 on the semiconductor chip 2220 using an insulating material such as a photoimageable dielectric (PID) resin, forming via holes 2243h opening the connection pads 2222, and then forming wiring patterns 2242 and vias 2243. Then, a passivation layer 2250 protecting the connection member 2240 may be formed, an opening 2251 may be formed, and an underbump metal layer 2260, or the like, may be formed. For example, a fan-in semiconductor package 2200 including, for example, the semiconductor chip 2220, the connection member 2240, the passivation layer 2250, and the underbump metal layer 2260 may be manufactured through a series of processes.

As described above, the fan-in semiconductor package may have a package form in which all of the connection pads, for example, input/output (I/O) terminals, of the semiconductor chip are disposed inside the semiconductor chip, and may have excellent electrical characteristics and be produced at a low cost. Therefore, many elements mounted in smartphones have been manufactured in a fan-in semiconductor package form. In detail, many elements mounted in smartphones have been developed to implement a rapid signal transfer while having a compact size.

However, since all I/O terminals need to be disposed inside the semiconductor chip in the fan-in semiconductor package, the fan-in semiconductor package has significant spatial limitations. Therefore, it is difficult to apply this structure to a semiconductor chip having a large number of I/O terminals or a semiconductor chip having a compact size. In addition, due to the disadvantage described above, the fan-in semiconductor package may not be directly mounted and used on the mainboard of the electronic device. The reason is that even though a size of the I/O terminals of the semiconductor chip and an interval between the I/O terminals of the semiconductor chip are increased by a redistribution process, the size of the I/O terminals of the semiconductor chip and the interval between the I/O terminals of the semiconductor chip are not enough to directly mount the fan-in semiconductor package on the mainboard of the electronic device.

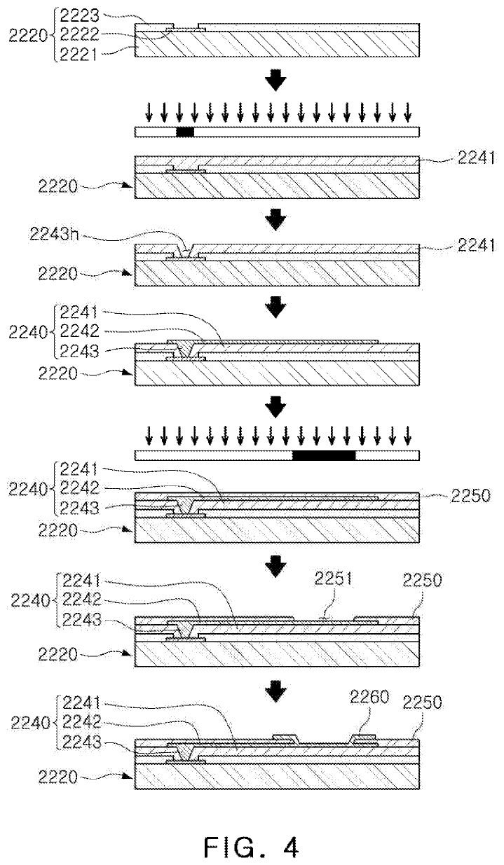

FIG. 5 is a schematic cross-sectional view illustrating a case in which a fan-in semiconductor package is mounted on a printed circuit board (PCB) substrate and is ultimately mounted on a mainboard of an electronic device.

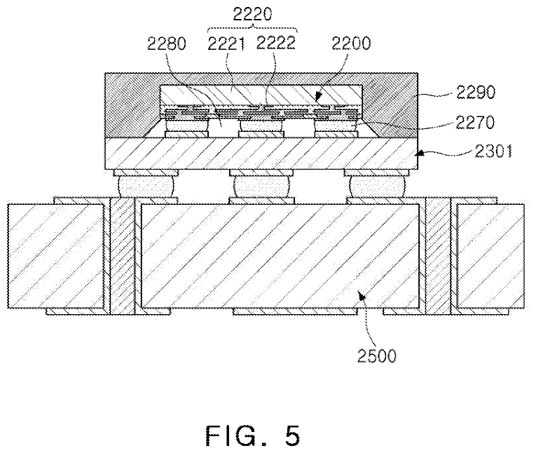

FIG. 6 is a schematic cross-sectional view illustrating a case in which a fan-in semiconductor package is embedded in a printed circuit board (PCB) and is ultimately mounted on a mainboard of an electronic device.

Referring to FIGS. 5 and 6, in a fan-in semiconductor package 2200, connection pads 2222, For example, I/O terminals, of a semiconductor chip 2220 may be redistributed through a printed circuit board 2301, and the fan-in semiconductor package 2200 may be ultimately mounted on a mainboard 2500 of an electronic device in a state in which it is mounted on the PCB 2301. In this case, solder balls 2270, and the like, may be fixed by an underfill resin 2280, or the like, and an outer side of the semiconductor chip 2220 may be covered with a molding material 2290, or the like. Alternatively, a fan-in semiconductor package 2200 may be embedded in a separate PCB 2302, connection pads 2222, For example, I/O terminals, of the semiconductor chip 2220 may be redistributed by the PCB 2302 in a state in which the fan-in semiconductor package 2200 is embedded in the PCB 2302, and the fan-in semiconductor package 2200 may be ultimately mounted on a mainboard 2500 of an electronic device.

As described above, it may be difficult to directly mount and use the fan-in semiconductor package on the mainboard of the electronic device. Therefore, the fan-in semiconductor package may be mounted on the separate PCB and be then mounted on the mainboard of the electronic device through a packaging process or may be mounted and used on the mainboard of the electronic device in a state in which it is embedded in the PCB.

Fan-out Semiconductor Package

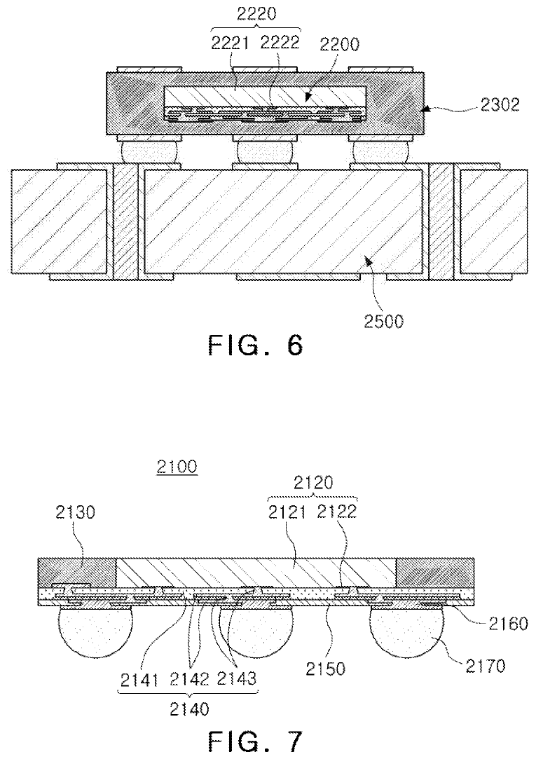

FIG. 7 is a schematic cross-sectional view illustrating a fan-out semiconductor package.

Referring to FIG. 7, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by a connection member 2140. In this case, a passivation layer 2150 may further be formed on the connection member 2140, and an underbump metal layer 2160 may further be formed in openings of the passivation layer 2150. Solder balls 2170 may further be formed on the underbump metal layer 2160. The semiconductor chip 2120 may be an integrated circuit (IC) including a body 2121, the connection pads 2122, a passivation layer (not illustrated), and the like. The connection member 2140 may include an insulating layer 2141, redistribution layers 2142 formed on the insulating layer 2141, and vias 2143 electrically connecting the connection pads 2122 and the redistribution layers 2142 to each other.

As described above, the fan-out semiconductor package may have a form in which I/O terminals of the semiconductor chip are redistributed and disposed outwardly of the semiconductor chip through the connection member formed on the semiconductor chip. As described above, in the fan-in semiconductor package, all I/O terminals of the semiconductor chip need to be disposed inside the semiconductor chip. Therefore, when a size of the semiconductor chip is decreased, a size and a pitch of balls need to be decreased, such that a standardized ball layout may not be used in the fan-in semiconductor package. On the other hand, the fan-out semiconductor package has the form in which the I/O terminals of the semiconductor chip are redistributed and disposed outwardly of the semiconductor chip through the connection member formed on the semiconductor chip as described above. Therefore, even in a case in which a size of the semiconductor chip is decreased, a standardized ball layout may be used in the fan-out semiconductor package as it is, such that the fan-out semiconductor package may be mounted on the mainboard of the electronic device without using a separate PCB, as described below.

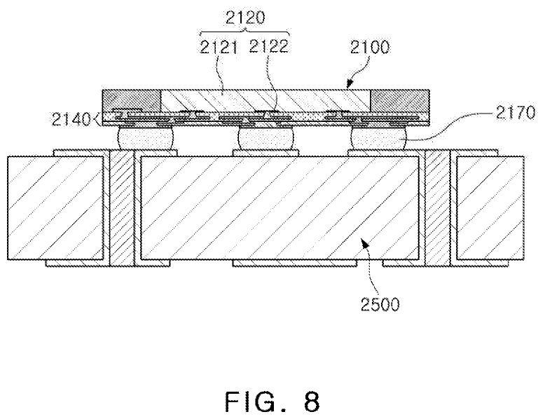

FIG. 8 is a schematic cross-sectional view illustrating a case in which a fan-out semiconductor package is mounted on a mainboard of an electronic device.

Referring to FIG. 8, a fan-out semiconductor package 2100 may be mounted on a mainboard 2500 of an electronic device through solder balls 2170, or the like. For example, as described above, the fan-out semiconductor package 2100 includes the connection member 2140 formed on the semiconductor chip 2120 and capable of redistributing the connection pads 2122 to a fan-out region that is outside of a size of the semiconductor chip 2120, such that the standardized ball layout may be used in the fan-out semiconductor package 2100 as it is. As a result, the fan-out semiconductor package 2100 may be mounted on the mainboard 2500 of the electronic device without using a separate PCB, or the like.

As described above, since the fan-out semiconductor package may be mounted on the mainboard of the electronic device without using the separate printed circuit board, the fan-out semiconductor package may be implemented at a thickness lower than that of the fan-in semiconductor package using the printed circuit board. Therefore, the fan-out semiconductor package may be miniaturized and thinned. In addition, the fan-out electronic component package has excellent thermal characteristics and electrical characteristics, such that it is particularly appropriate for a mobile product. Therefore, the fan-out electronic component package may be implemented in a form more compact than that of a general package-on-package (POP) type using a printed circuit board (PCB), and may solve a problem due to the occurrence of a warpage phenomenon.

Meanwhile, the fan-out semiconductor package refers to package technology for mounting the semiconductor chip on the mainboard of the electronic device, or the like, as described above, and protecting the semiconductor chip from external impacts, and is a concept different from that of a printed circuit board (PCB) such as a PCB, or the like, having a scale, a purpose, and the like, different from those of the fan-out semiconductor package, and having the fan-in semiconductor package embedded therein.

Hereinafter, a fan-out semiconductor package having an excellent electromagnetic wave shielding effect and an excellent heat radiation effect will be described with reference to the drawings.

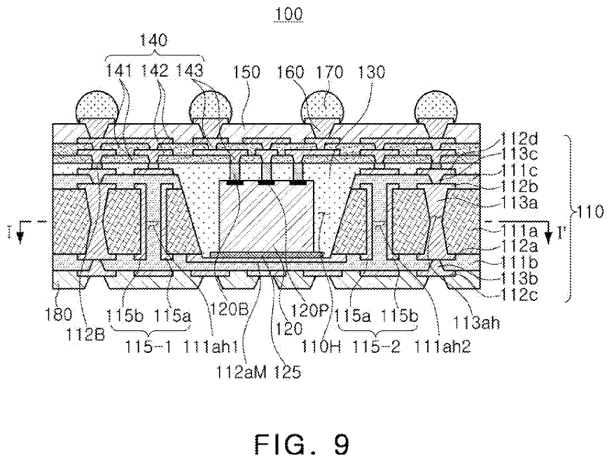

FIG. 9 is a cross-sectional view schematically illustrating an example of a fan-out semiconductor package.

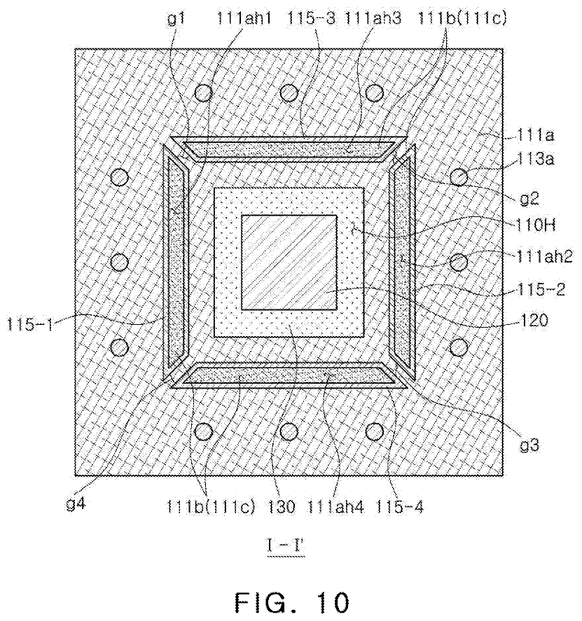

FIG. 10 is a schematic cross-sectional plan view of the fan-out semiconductor package of FIG. 9.

Referring to the drawings, a fan-out semiconductor package 100 according to an example includes a frame 110 having a recess portion 110H, a semiconductor chip 120 having a connection pad 120P and disposed in the recess portion 110H, a plurality of through-grooves 111ah1, 111ah2, 111ah3 and 111ah4 disposed around the recess portion 110H, respectively penetrating through at least a portion of the frame 110 to extend in one direction along a respective side surface of the semiconductor chip 120, and spaced apart from each other by a predetermined distance, a plurality of metal layers 115-1, 115-2, 115-3 and 115-4 disposed on side walls of the plurality of through-grooves 111ah1, 111ah2, 111ah3 and 111ah4, respectively, an encapsulant 130 covering at least a portion of each of the frame 110 and the semiconductor chip 120 and filling at least a portion of the recess portion 110H, and a connection structure 140 disposed on the frame 110 and the semiconductor chip 120 and including a redistribution layer 142 electrically connected to the connection pad 120P. The plurality of through-grooves 111ah1, 111ah2, 111ah3 and 111ah4, and the plurality of metal layers 115-1, 115-2, 115-3 and 115-4 disposed on side walls of the plurality of through-grooves 111ah1, 111ah2, 111ah3 and 111ah4, respectively, may be disposed in the frame 110 as shielding members.

As described above, in the case of the fan-out semiconductor package 100 according to the example, the plurality of through-grooves 111ah1, 111ah2, 111ah3 and 111ah4 having, for example, a trench shape, are disposed around the recess portion 110H in which the semiconductor chip 120 is disposed, to each extend in one direction along a respective side surface of the semiconductor chip 120 to surround the recess portion in the frame 110. In this case, the plurality of metal layers 115-1, 115-2, 115-3 and 115-4 are disposed on sidewalls of the plurality of through-grooves 111ah1, 111ah2, 111ah3 and 111ah4, respectively. By surrounding the periphery of the semiconductor chip 120 with a metal material, an excellent electromagnetic wave shielding effect may be obtained. In this case, extending in one direction is not merely formed in the shape of a hole but also extends in a length in the specific direction that is significantly longer than the length in the direction perpendicular thereto as viewed from the plane as illustrated in FIG. 10 by way of example, which may be the so-called trench shape.

The plurality of metal layers 115-1, 115-2, 115-3 and 115-4 are formed as conformal-type layers to have a predetermined thickness along the side walls of the plurality of through-grooves 111ah1, 111ah2, 111ah3 and 111ah4. In this case, double metal layers 115a and 115b are disposed in each of the through-grooves 111ah1, 111ah2, 111ah3 and 111ah4, based on the semiconductor chip 120, thereby further improving an electromagnetic wave shielding effect. A gap between the respective double metal layers 115a and 115b of the through-grooves 111ah1, 111ah2, 111ah3 and 111ah4 may be filled with an insulating material 111b or 111c.

The frame 110 may include a plurality of wiring layers 112a, 112b, 112c and 112d electrically connected to each other via a plurality of wiring via layers 113a, 113b and 113c. A stopper layer 112aM, which is disposed on the same level as one wiring layer 112a of the plurality of wiring layers 112a, 112b, 112c and 112d and includes a metal material, may be disposed on the bottom surface of the recess portion 110H. The semiconductor chip 120 may be disposed in the recess portion 110H in such a manner that an inactive surface thereof faces the stopper layer 112aM. As described above, when the recess portion 110H of a blind type is introduced into the frame 110 through the stopper layer 112aM and the semiconductor chip 120 is disposed therein, the inactive surface side of the semiconductor chip 120 is also covered with the metal material, thereby exhibiting more excellent electromagnetic wave shielding and heat dissipation effects. Since the stopper layer 112aM may be formed together with the wiring layer 112a on the frame 110, the process may be simplified.

On the other hand, wiring vias of one wiring via layer 113a of the plurality of wiring via layers 113a, 113b and 113c of the frame 110 may be disposed on the same level as the plurality of through-grooves 111ah1, 111ah2, 111ah3, and 111ah4. In this case, the wiring vias of the one wiring via layer 113a may be formed as filled-type vias by respectively filling a through-hole 113ah, which penetrates through at least a portion of the frame 110 in a hole shape, with a metal material in a filled-type. In this case, other wirings and vias connected to the wiring vias of the wiring via layer 113a may be designed with a higher density by a stacked type or the like, thereby obtaining superior signal transmission reliability. For example, the wiring vias provided as the electrical connection path may be formed in a form in which the through-hole 113ah, penetrating through at least a portion of the frame 110 in the form of a hole, is filled with a metal material. In a manner different therefrom, a shielding member is formed to have a form in which a metal material is respectively conformally disposed in the through-grooves 111ah1, 111ah2, 111ah3 and 111ah4, penetrating through at least a portion of the frame 110 in the form of a trench, such that a design may be carried out appropriately according to the function of each member or via.

Hereinafter, each configuration included in the fan-out semiconductor package 100 according to an example will be described in more detail.

The frame 110 may further improve the rigidity of the fan-out semiconductor package 100 according to a detailed material of insulating layers 111a, 111b and 111c, and may serve to ensure thickness uniformity of the encapsulant 130. In addition, the frame 110 includes the wiring layers 112a, 112b, 112c and 112d and wiring via layers 113a, 113b and 113c, and thus, may serve as an electrical connection structure for vertical electrical connection, and a problem relevant to a yield of the semiconductor chip 120 due to defects that may occur in the process of forming the connection structure 140 may be reduced. Since the frame 110 includes the third wiring layer 112c disposed to be lower than an inactive surface of the semiconductor chip 120, a backside wiring layer for the semiconductor chip 120 may be provided without a separate backside wiring process.

The frame 110 may have a blind-type recess portion 110H formed by using the stopper layer 112aM as a stopper, and the semiconductor chip 120 may be attached to the stopper layer 112aM in such a manner that the inactive surface is attached thereto via an adhesive member 125 such as a die attach film (DAF), or the like. The recess portion 110H may be formed through a sand blast process or the like, and in this case, a cross-sectional shape thereof may be a tapered shape. For example, a sidewall of the recess portion 110H may have a predetermined slope, for example, an inclination, based on the stopper layer 112aM. In this case, since an aligning process of the semiconductor chip 120 may be further facilitated, the yield may be increased.

The frame 110 includes a core insulating layer 111a, first and second wiring layers 112a and 112b disposed on opposing surfaces of the core insulating layer 111a, respectively, first and second build-up insulating layers 111b and 111c which are disposed on the opposing surfaces of the core insulating layer 111a to cover the first and second wiring layers 112a and 112b, respectively, a third wiring layer 112c disposed on the first build-up insulating layer 111b, and a fourth wiring layer 112d disposed on the second build-up insulating layer 111c. Further, the frame 110 includes a first wiring via layer 113a penetrating through the core insulating layer 111a and electrically connecting the first and second wiring layers 112a and 112b, a second wiring via layer 113b penetrating through the second build-up insulating layer 111b and electrically connecting the first and third wiring layers 112a and 112c, and a third wiring via layer 113c penetrating through the second build-up insulating layer 111c and electrically connecting the second and fourth wiring layers 112b and 112d.

The first to fourth wiring layers 112a, 112b, 112c and 112d of the frame 110 are electrically connected to each other and electrically connected to the connection pads 120P of the semiconductor chip 120, respectively. The recess portion 110H may penetrate through the core insulating layer 111a and the second build-up insulating layer 111c, but may not penetrate through the first build-up insulating layer 111b. The stopper layer 112aM may be disposed on a lower surface of the core insulating layer 111a and covered with the first build-up insulating layer 111b. The first build-up insulating layer 111b and the second build-up insulating layer 111c, and the wiring layers 112c and 112d and the wiring via layers 113b and 113c, formed thereon, may be configured in a relatively larger number. The first build-up insulating layer 111b and the second build-up insulating layer 111c, and the wiring layers 112c and 112d and the wiring via layers 113b and 113c, are disposed to be substantially symmetrical with respect to the core insulating layer 111a.

The stopper layer 112aM may be a metal layer including a metal material such as copper (Cu), and alternatively, may include an insulating material having a smaller etching rate for the sandblasting than a metal, for example, dry film photoresist. For example, in the case in which the stopper layer 112aM is a metal layer including a metal material, the metal layer may be formed together when the first wiring layer 112a of the frame 110 is formed, which may be advantageous in terms of simplifying a manufacturing process, and the inactive surface of the semiconductor chip 120 may thereby be covered with a metal material, which is also advantageous in providing electromagnetic wave shielding and heat radiation. In the case in which the stopper layer 112aM is a metal layer including a metal material, the stopper layer 112aM may be used as a ground, and in this case, may be electrically connected to a ground pattern of at least one of the wiring layers 112a, 112b, 112c and 112d.

A lower surface of the stopper layer 112aM is covered with the first build-up insulating layer 111b, and at least a portion of an upper surface thereof may be exposed by the recess portion 110H. In the case of the stopper layer 112aM, a thickness of a region thereof exposed from the core insulating layer 111a by the recess portion 110H is less than a thickness of an edge region thereof which is not exposed from the core insulating layer 111a by the recess portion 110H, which is because an exposed region of the stopper layer 112aM may also be partially removed in a sandblast process.

As the material of the insulating layers 111a, 111b and 111c, an insulating material may be used. As the insulating material, a thermosetting resin such as an epoxy resin, a thermoplastic resin such as polyimide, a mixture of these resins with an inorganic filler, or a resin impregnated with a core material such as a glass fiber, a glass cloth, a glass fabric, or the like, together with an inorganic filler, for example, a prepreg resin, Ajinomoto Build-up Film (ABF) resin, FR-4 resin, Bismaleimide Triazine (BT) resin, or the like, may be used. In the case in which a rigid material such as a prepreg including glass fiber or the like is used, the frame 110 may be utilized as a support member for controlling warpage of the fan-out semiconductor package 100.

The core insulating layer 111a may have a thickness greater than that of each of the first and second build-up insulating layers 111b and 111c. The core insulating layer 111a may have a relatively great thickness to maintain rigidity, and the first build-up insulating layer 111b and the second build-up insulating layer 111c may be employed to form a relatively large number of wiring layers 112c and 112d. The core insulating layer 111a may be introduced through a relatively thick copper-clad laminate (CCL), and the first build-up insulating layer 111b and the second build-up insulating layer 111c may be introduced through relatively thin prepreg or ABF, but an example thereof is not limited thereto. Similarly, the first wiring via layer 113a penetrating through the core insulating layer 111a may have an average diameter greater than that of the second and third wiring via layers 113b and 113c passing through the first and second build-up insulating layers 111b and 111c.

The wiring layers 112a, 112b, 112c and 112d may redistribute the connection pads 120P of the semiconductor chip 120 together with the redistribution layer 142, and in addition, may provide a vertical electrical connection path of the fan-out semiconductor package 100. As a material for formation of the respective wiring layers 112a, 112b, 112c and 112d, a metal material such as copper (Cu), aluminum (Al), silver (Ag), tin (Sn), gold (Au), nickel (Ni), lead (Pb), titanium (Ti), or alloys thereof may be used. The wiring layers 112a, 112b, 112c and 112d may perform various functions according to the design of a relevant layer. For example, the wiring layers 112a, 112b, 112c and 112d may include a ground (GrouND: GND) pattern, a power (PoWeR: PWR) pattern, a signal (Signal: S) pattern, and the like. The ground (GND) pattern and the power (PWR) pattern may be formed in the same pattern, but an example thereof is not limited thereto. The signal S pattern includes various signals except for the ground (GND) pattern, the power (PWR) pattern and the like, for example, may include a data signal and the like, and in addition, may include various pad patterns.

The thickness of each of the wiring layers 112a, 112b, 112c and 112d may be greater than the thickness of each of the redistribution layers 142 of the connection structure 140. The frame 110 may have a thickness equal to or greater than that of the semiconductor chip 120, and thus, the wiring layers 112a, 112b, 112c and 112d may also be formed in a relatively larger size. On the other hand, the redistribution layer 142 of the connection structure 140 may be formed in a relatively small size for fine design and thinning.

The wiring via layers 113a, 113b and 113c electrically connect the wiring layers 112a, 112b, 112c and 112d formed in different layers, thereby forming an electrical path in the frame 110. The wiring via layers 113a, 113b and 113c may also be formed using a metal material such as copper (Cu), aluminum (Al), silver (Ag), tin (Sn), gold (Au), nickel (Ni), lead (Pb), titanium (Ti), or alloys thereof. The wiring via layers 113a, 113b, and 113c may be filled-type layers fully filled with a metal material. The first wiring via layer 113a may have a cylindrical sectional shape or an hourglass shape, and the second and third wiring via layers 113b and 113c may have a tapered shape. In this case, the wiring vias of the second and third wiring via layers 113b and 113c may be tapered in opposite directions with respect to each other, based on the core insulating layer 111a.

Although not illustrated in the drawing, at least one wiring via in the second wiring via layer 113b may be connected to the stopper layer 112aM, and may be connected to the power and/or ground pattern of the third wiring layer 112c. For example, the power and/or ground pattern of the stopper layer 112aM and the third wiring layer 112c may be connected. In this case, the stopper layer 112aM may be a metal layer including a metal material, and thus, may function as a power and/or ground pattern. Thus, heat emitted through the inactive surface of the semiconductor chip 120 may be easily discharged to the lower portion of the fan-out semiconductor package 100.

The through-grooves 111ah1, 111ah2, 111ah3 and 111ah4 are respectively disposed around the recess portion 110H in which the semiconductor chip 120 is disposed. The through-grooves 111ah1, 111ah2, 111ah3 and 111ah4 are respectively disposed around the recess portion 110H to each extend in one respective direction along a respective side surface of the semiconductor chip 120, and to penetrate through at least portions of the frame 110, for example, through the core insulating layer 111a to have the form of a trench. The metal layers 115-1, 115-2, 115-3 and 115-4 are disposed on side walls of the through-grooves 111ah1, 111ah2, 111ah3 and 111ah4, respectively, and the metal layers 115-1, 115-2, 115-3 and 115-4 are conformally disposed. In this case, the double metal layers 115a and 115b are disposed in each of the through-grooves 111ah1, 111ah2, 111ah3 and 111ah4, thereby further improving an electromagnetic wave shielding effect. A gap between the respective double metal layers 115a and 115b of the through-grooves 111ah1, 111ah2, 111ah3 and 111ah4 may be filled with an insulating material of the second build-up insulating layer 111b and/or of the third build-up insulating layer 111c.

The through-grooves (111ah1, 111ah2, 111ah3 and 111ah4) may include first to fourth through-grooves 111ah1, 111ah2, 111ah3 and 111ah4, each respectively formed in the form of a trench along a different respective one of four side surfaces of the semiconductor chip 120. In this case, the first to fourth through-grooves 111ah1, 111ah2, 111ah3 and 111ah4 are spaced apart from each other by a predetermined distance to have four gaps g1, g2, g3 and g4 in regions corresponding to four corner portions of the semiconductor chip 120. The presence of the gaps g1, g2, g3 and g4 may prevent the core insulating layer 111a from being disconnected, thereby preventing occurrence of a problem such as misalignment of disconnected portions in a manufacturing process. The shapes of the through-grooves 111ah1, 111ah2, 111ah3 and 111ah4 may be variously modified as long as they surround the semiconductor chip 120. In this case, at least one of the gaps g1, g2, g3 and g4 may be provided to prevent the core insulating layer 111a from being disconnected. Optionally, one through-groove may be employed in such a manner that one end and the other end thereof are spaced apart from each other by a predetermined distance of a gap (e.g., g1), while being continuously formed to surround the semiconductor chip 120.

The metal layers 115-1, 115-2, 115-3 and 115-4 may include a metal such as copper (Cu), aluminum (Al), silver (Ag), tin (Sn), gold (Au), nickel (Ni), lead (Pb), titanium (Ti), or alloys thereof. In this case, the metal layers 115-1, 115-2, 115-3 and 115-4 are electrically insulated from a signal pattern of a plurality of wiring layers 112a, 112b, 112c and 112d, respectively, but may be electrically connected to a ground pattern and/or a power pattern.

The semiconductor chip 120 may be an integrated circuit (IC) in which hundreds to millions or more of devices are integrated in a single chip. The semiconductor chip 120 may be a processor chip such as a central processor (for example, a central processing unit (CPU)), a graphics processor (for example, a graphics processing unit (GPU)), a field programmable gate array (FPGA), a digital signal processor (DSP), a cryptographic processor, a microprocessor, a microcontroller, or the like, in detail, an application processor (AP), but an example thereof is not limited thereto. In addition, the semiconductor chip 120 may be a memory such as a volatile memory (for example, a dynamic random access memory (DRAM)), a non-volatile memory (for example, a read only memory (ROM)), a flash memory, or the like, or may be a logic such as an analog-to-digital (ADC) converter, an application-specific integrated circuit (ASIC), or the like.

The semiconductor chip 120 may be formed based on an active wafer. As a base material forming a body thereof, silicon (Si), germanium (Ge), gallium arsenide (GaAs) or the like may be used. The body may include various circuits formed therein. The connection pad 120P disposed on the active surface of the body is provided to electrically connect the semiconductor chip 120 to other components. The connection pad 120P may be formed using a metal material such as aluminum (Al), copper (Cu) or the like without particular limit. A passivation film (not illustrated) such as an oxide film or a nitride film that exposes the connection pad 120P may be formed on the active surface of the body, and the passivation film (not illustrated) may be a double layer of an oxide film and a nitride film. The passivation film (not illustrated) may have an opening (not illustrated) exposing at least a portion of the connection pad 120P. An insulating film (not illustrated) or the like may be further disposed in an appropriate position. The semiconductor chip 120 may be a bare die or may also be a packaged die in which an insulating layer (not illustrated), a redistribution layer (not illustrated), a bump (not illustrated) and the like are formed on the active surface.

A first connection member 120B may be introduced to electrically connect the connection pad 120P of the semiconductor chip 120 to the redistribution layer 142 of the connection structure 140. The first connection member 120B may be a metal post or a metal pillar, such as a copper post or a copper pillar, but an example thereof is not limited thereto. By introducing the first connection member 120B, the connection pad 120P may be electrically connected to the redistribution layer 142 of the connection structure 140 easily, regardless of the thickness of the semiconductor chip 120. The first connection member 120B may have a substantially vertical side surface. The number of the first connection members 120B is not particularly limited, and may be variously applied depending on the number of the connection pads 120P. The first connection member 120B is electrically connected to the redistribution layer 142 through a first connection via of the connection vias 143 of the connection structure 140, and may physically contact the first connection via.

A second connection structure 112B may be introduced to electrically connect an uppermost wiring layer 112d of the frame 110 to the redistribution layer 142 of the connection structure 140. The second connection structure 112B may also be a metal post, such as a copper post, but an example thereof is not limited thereto. By introducing the second connection structure 112B, a problem such as a copper burr, which may occur while the surface of the fourth wiring layer 112d, an uppermost wiring layer, is processed in a grinding process, may be reduced. The second connection structure 112B may also have a substantially vertical side surface. The number of the second connection members 112B is not particularly limited, and may be variously applied according to the design of the pattern of the uppermost wiring layer 112d. The second connection structure 112B is electrically connected to the redistribution layer 142 through a second connection via of the connection vias 143 of the connection structure 140, and may physically contact the second connection via.

The encapsulant 130 covers at least a portion of each of the frame 110, the semiconductor chip 120, and the first and second connection members 120B and 112B, and fills at least a portion of the recess portion 110H. The material of the encapsulant 130 is not particularly limited. For example, an insulating material may be used. As the insulating material, a thermosetting resin such as an epoxy resin, a thermoplastic resin such as polyimide, or a mixture of these resins with an inorganic filler, or a resin impregnated with a core material such as a glass fiber or the like together with an inorganic filler, for example, a prepreg resin, Ajinomoto Build-up Film (ABF) resin, FR-4 resin, Bismaleimide Triazine (BT) resin, or the like, may be used. A photoimageable dielectric material, for example, a Photo Imageable Encapsulant (PIE) may be used.

The encapsulant 130 is provided, in which the first and second connection members 120B and 112B are embedded in such a manner that an upper surface of each of the first and second connection members 120B and 112B, contacting the connection structure 140, is exposed from an upper surface of the encapsulant 130 contacting the connection structure 140. In this case, the upper surface of each of the first and second connection members 120B and 112B may be disposed substantially on the same plane as the upper surface of the encapsulant 130, to be coplanar with each other, which is because the first and second connection members 120B and 112B and the encapsulant 130 are simultaneously subjected to grinding processing. In this case, the coplanar is a concept including not only being present on exactly the same plane but also present on approximately the same plane. In this case, a flat surface is provided in the manufacturing process of the connection structure 140, such that a micro-design of the connection structure 140 may be relatively easier.

The connection structure 140 may redistribute the connection pads 120P of the semiconductor chip 120, and may electrically connect the wiring layers 112a, 112b, 112c and 112d of the frame 110 to the connection pads 120P of the semiconductor chip 120. Tens to millions of connection pads 120P having various functions may be redistributed through the connection structure 140, and may be physically and/or electrically connected externally through an electrical connection structure 170 according to functions thereof.

The connection structure 140 includes an insulating layer 141 disposed on the coplanar surface described above, the redistribution layer 142 disposed on the insulating layer 141, and the connection via 143 including first and second connection vias electrically connecting the redistribution layer 142 to the first and second connection members 120B and 112B while penetrating through the insulating layer 141. The insulating layer 141, the redistribution layer 142, and the connection via 143 as illustrated in the drawings may be composed of a relatively larger number of layers or may be composed of a relatively smaller number of layers.

As the material of the insulating layer 141, an insulating material may be used. In addition to the insulating material as described above, a photoimageable dielectric material such as a Photo Imageable Dielectric (PID) resin may be used as the insulating material. For example, the insulating layer 141 may be a photoimageable dielectric layer. In the case in which the insulating layer 141 has photoimageable properties, the insulating layer 141 may be formed to have a further reduced thickness, and a fine pitch of the connection via 143 may be more easily obtained. The insulating layer 141 may be a photoimageable dielectric layer containing an insulating resin and an inorganic filler. When the insulating layer 141 is formed of multiple layers, materials thereof may be the same as each other, and may be different from each other as needed. When the insulating layer 141 is formed of multiple layers, the multiple layers may be integrated according to a process, and boundaries therebetween may be unclear.

The redistribution layer 142 may serve to redistribute the connection pads 120P. As a material of the redistribution layer 142, a metal material such as copper (Cu), aluminum (Al), silver (Ag), tin (Sn), gold (Au), nickel (Ni), lead (Pb), titanium (Ti), or alloys thereof may be used. The redistribution layer 142 may perform various functions according to the design of a relevant layer. For example, the redistribution layer 142 may include a ground (GrouND: GND) pattern, a power (PoWeR: PWR) pattern, a signal (Signal: S) pattern, and the like. The ground (GND) pattern and the power (PWR) pattern may be formed in the same pattern, but an example thereof is not limited thereto. The signal S pattern includes various signals except the ground (GND) pattern, the power (PWR) pattern and the like, for example, may include a data signal and the like, and in addition, may include various pad patterns.

The connection via 143 electrically connects the redistribution layer 142, the first and second connection members 120B and 112B, and the like, formed on different layers, thereby forming an electrical path in the fan-out semiconductor package 100. The connection via 143 may function as a signal via, a ground via, a power via, and the like. The connection via 143 may be formed using a metal material such as copper (Cu), aluminum (Al), silver (Ag), tin (Sn), gold (Au), nickel (Ni), lead (Pb), titanium (Ti), or alloys thereof. The connection via 143 may be a filled-type via filled with a metal material, or may be a conformal-type via formed as a metal material is formed along a wall of a via hole, and further, may have a tapered cross-sectional shape or the like.

A first passivation layer 150 may be an additional configuration to protect the connection structure 140 from external physical chemical damage or the like. The first passivation layer 150 may have an opening that exposes at least a portion of an uppermost redistribution layer 142c of the connection structure 140. The opening may be formed in tens to tens of thousands in the first passivation layer 150. The material of the first passivation layer 150 is not particularly limited. For example, an insulating material may be used. As the insulating material, a thermosetting resin such as an epoxy resin, a thermoplastic resin such as polyimide, or a mixture of these resins with an inorganic filler, or a resin impregnated with a core material such as a glass fiber or the like together with an inorganic filler, for example, a prepreg resin, Ajinomoto Build-up Film (ABF) resin, FR-4 resin, Bismaleimide Triazine (BT) resin, or the like, may be used. A solder resist may also be used.

An underbump metal layer 160 may be an additional configuration to improve connection reliability of the electrical connection structure 170, thereby improving board level reliability of the fan-out semiconductor package 100. The underbump metal layer 160 is connected to an uppermost redistribution layer 142 of the connection structure 140 exposed through the opening of the first passivation layer 150. The underbump metal layer 160 may be formed by forming a metal material, for example, a metal, in the opening of the first passivation layer 150, using a metallization method such as a plating process.

The electrical connection structure 170 is also an additional configuration to physically and/or electrically connect the fan-out semiconductor package 100 according to an example externally. For example, the fan-out semiconductor package 100 according to an example may be mounted on a main board of an electronic device through the electrical connection structure 170. The electrical connection structure 170 may be formed of a low melting point metal, for example, a material including tin (Sn), in more detail, solder or the like, which is merely an example. The material thereof is not particularly limited. The electrical connection structure 170 may be a land, a ball, a pin, or the like. The electrical connection structure 170 may be formed of a multilayer or a single layer. In the case in which the electrical connection structure 170 is formed of multiple layers, a copper pillar and solder may be included therein. In the case of a single layer, a tin-silver solder or copper may be included in the electrical connection structure 170 as an example, and a material thereof is not limited thereto.

The number, spacing, arrangement type and the like of the electrical connection structure 170 are not particularly limited, and may be sufficiently modified according to the design specifications by those skilled in the art. For example, the number of the electrical connection metals 170 may be in the range of tens to tens of thousands depending on the number of the connection pads 120P, and may be more or less thereof. For example, when the electrical connection structure 170 is a solder ball, the electrical connection structure 170 may cover a side surface of the underbump metal layer 160 extending on one surface of the first passivation layer 150, and in this case, connection reliability may be relatively further excellent.

At least one of the electrical connection structures 170 is disposed in a fan-out region. The fan-out region refers to an area outside an area in which the semiconductor chip 120 is disposed. In the case of the fan-out package, reliability is relatively excellent, a large number of I/O terminals may be implemented, and 3D interconnection may be facilitated, as compared with those of a fan-in package. In addition, compared with a ball grid array (BGA) package, a land grid array (LGA) package or the like, a package thickness may be reduced and excellent price competitiveness may be provided in the case of the fan-out package.

A second passivation layer 180 may be an additional configuration to protect the frame 110 from external physical chemical damage or the like. The second passivation layer 180 may have an opening that exposes at least a portion of the third wiring layer 112c, a lowermost wiring layer of the frame 110. The opening may be formed in tens to tens of thousands in the second passivation layer 180. A material of the second passivation layer 180 is not particularly limited. For example, an insulating material may be used. As the insulating material, a thermosetting resin such as an epoxy resin, a thermoplastic resin such as polyimide, or a mixture of these resins with an inorganic filler, or a resin impregnated with a core material such as a glass fiber or the like together with an inorganic filler, for example, a prepreg resin, Ajinomoto Build-up Film (ABF) resin, FR-4 resin, Bismaleimide Triazine (BT) resin, or the like, may be used. A solder resist may also be used.

On the other hand, although not illustrated in the drawing, a metal thin film may be further formed on a side wall of the recess portion 110H for heat radiation and/or for shielding electromagnetic waves. Further, a plurality of semiconductor chips 120 that perform the same or different functions may also be disposed in the recess portion 110H. In addition, a separate passive component such as an inductor, a capacitor or the like may be disposed in the recess portion 110H. In addition, a passive component, for example, surface mount (SMT) components including an inductor, a capacitor or the like may also be disposed on the surfaces of the first and second passivation layers 150 and 180.

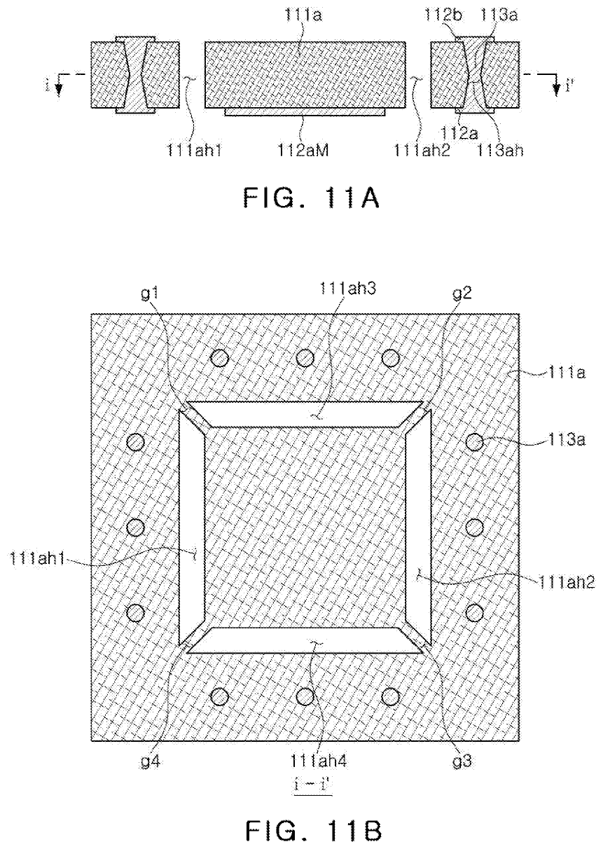

FIGS. 11A, 11B, 12A, 12B, 13A, 13B, 14A, and 14B are schematic views illustrating a process of manufacturing a frame of the fan-out semiconductor package of FIG. 9.

Referring to FIGS. 11A and 11B, a core insulating layer 111a is first prepared using a copper clad laminate (CCL) or the like, and first and second wiring layers 112a and 112b, a stopper layer 112aM and a first wiring via layer 113a are formed, using a plating process, such as an additive process (AP), a semi-additive process (SAP), a modified semi-additive process (MSAP), or a tenting process or the like. A through-hole 113ah for the first wiring via layer 113a may be formed using mechanical drilling and/or laser drilling. Further, one or more through-grooves 111ah1, 111ah2, 111ah3 and 111ah4 may be formed to respectively penetrate through the core insulating layer 111a, using mechanical drilling and/or laser drilling. The through-grooves 111ah1, 111ah2, 111ah3 and 111ah4 are formed in a trench shape to extend in one direction along a side surface of a semiconductor chip 120, to surround the periphery of a region in which the stopper layer 112aM is formed, and to have one or more gaps g1, g2, g3 and g4 therebetween.

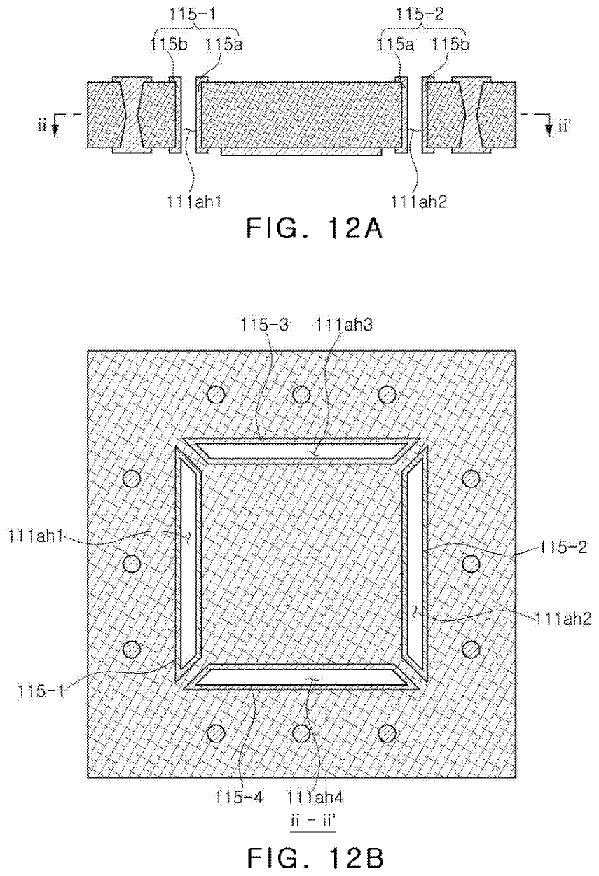

Next, referring to FIGS. 12A and 12B, metal layers 115-1, 115-2, 115-3 and 115-4 are formed on the through-grooves 111ah1, 111ah2, 111ah3 and 111ah4, respectively, using a plating process such as AP, SAP, MSAP, tenting or the like. Each of the metal layers 115-1, 115-2, 115-3 and 115-4 may be conformally formed to have a double metal layer 115a, 115b.

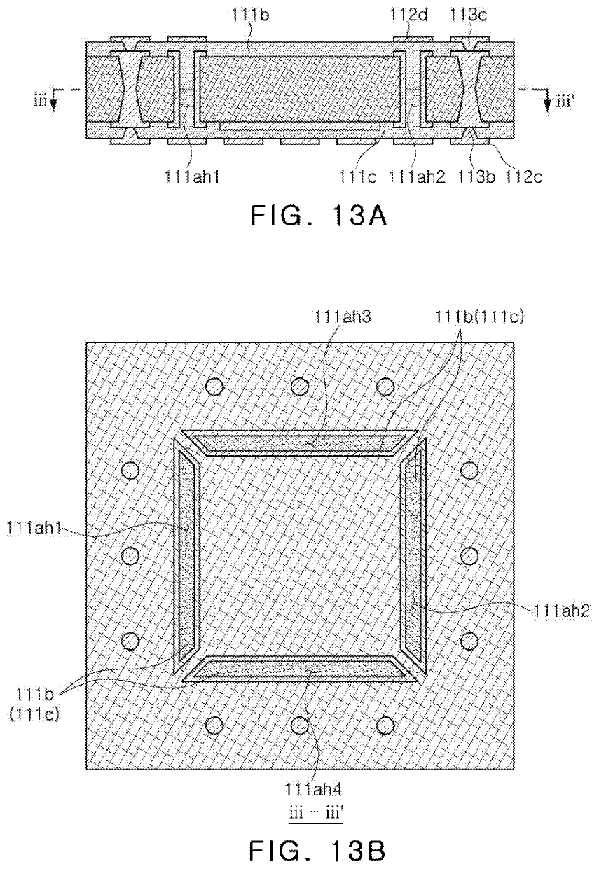

Subsequently, referring to FIGS. 13A and 13B, first and second build-up insulating layers 111b and 111c are formed on and under the core insulating layer 111a. The first and second build-up insulating layers 111b and 111c may be formed by a method of laminating and curing a prepreg, ABF, or the like. In this process, the respective through-grooves 111ah1, 111ah2, 111ah3 and 111ah4 may be filled with an insulating material of the first and/or second build-up insulating layers 111b and 111c. Next, third and fourth wiring layers 112c and 112d and second and third wiring via layers 113b and 113c are formed using a plating process such as AP, SAP, MSAP, tenting or the like. Via holes for the second and third wiring via layers 113b and 113c may also be formed using mechanical drilling and/or laser drilling.

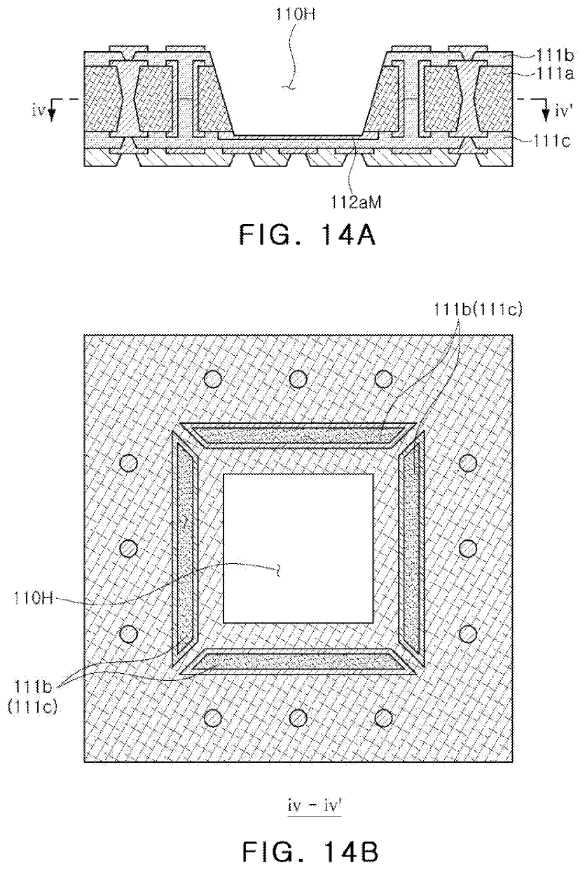

Next, referring to FIGS. 14A and 14B, after attaching a dry film (not illustrated) on an upper side of the frame 110, the recess portion 110H is formed to penetrate through the core insulating layer 111a and the second build-up insulating layer 111c, using sandblasting or the like, and then, the dry film (not illustrated) is removed. In this case, the recess portion 110H may not penetrate through the first build-up insulating layer 111b. When the recess portion 110H is formed, the stopper layer 112aM functions as a stopper. Through the series of processes, the frame 110 described above may be manufactured.

As set forth above, according to an example, a fan-out semiconductor package may have an excellent electromagnetic wave shielding effect, and furthermore, may have an excellent heat radiation effect.

The expressions, ‘coplanar’ or ‘on the same level’, in the present disclosure is meant to include not only being located at exactly the same level but also located at approximately the same level as a result of a grinding process or the like.

In the present disclosure, the lower side, the lower portion, the lower surface and the like refer to the downward direction with respect to the cross section of the drawings for convenience, and the upper side, the upper portion, and the upper surface are used in the opposite direction. It should be noted, however, that this is a definition of a direction for the sake of convenience of explanation, and the scope of rights of the claims is not particularly limited by description of such direction.

The meaning of being connected in the present disclosure encompasses not only a direct connection, but also includes an indirect connection through an adhesive or the like. In addition, the term “electrically connected” means a concept including both a physical connection and non-connection. Further, the first and second expressions are used to distinguish one component from another component and do not limit the order and/or importance of components and the like. In some cases, without departing from the scope of the rights, a first component may be referred to as a second component, and similarly, a second component may also be referred to as a first component.

The expression, an example, used in this disclosure does not mean the same embodiment, but is provided for emphasizing and explaining different unique features. However, the above-mentioned examples do not exclude being implemented in combination with the features of other examples. For example, although the description in the specific example is not described in another example, it may be understood as an explanation related to another example, unless otherwise described or contradicted by the other example.

The terms used in this disclosure are used only to illustrate an example and are not intended to limit the present disclosure, and the singular expressions include plural expressions unless the context clearly dictates otherwise.

What is claimed is:

1. A fan-out semiconductor package comprising:
a frame having a recess portion;
a semiconductor chip having an active surface on which a connection pad is disposed and an inactive surface opposing the active surface, the semiconductor chip being disposed in the recess portion;
one or more through-grooves disposed around the recess portion and each penetrating through at least a portion of the frame to each extend in a respective direction along a respective side surface of the semiconductor chip;
a metal layer disposed on side walls of the one or more through-grooves;
an encapsulant covering at least a portion of each of the frame and the semiconductor chip and filling at least a portion of the recess portion; and
a connection structure disposed on the frame and the active surface of the semiconductor chip, and including a redistribution layer electrically connected to the connection pad.

2. The fan-out semiconductor package of claim 1, wherein the metal layer is conformally disposed to have a predetermined thickness along the side walls of the one or more through-grooves, and
a gap between the metal layer disposed on opposing side walls of one of the one or more through-grooves is filled with an insulating material.

3. The fan-out semiconductor package of claim 2, wherein the frame comprises first and second wiring layers disposed on different levels, and one or more wiring vias electrically connecting the first and second wiring layers to each other, and
wherein the one or more wiring vias are each provided in such a manner that a respective through-hole, penetrating through at least a portion of the frame in the form of a hole, is filled with a metal material.

4. The fan-out semiconductor package of claim 3, wherein the one or more through-grooves and the through-hole extend between the same set of opposing surfaces of the frame.

5. The fan-out semiconductor package of claim 1, wherein the one or more through-grooves include a plurality of through-grooves, and
wherein the through-grooves of the plurality of through-grooves are disposed around the recess portion, respectively penetrate through at least a portion of the frame, each extend along a respective side surface of the semiconductor chip, and are spaced apart from each other by a predetermined distance.

6. The fan-out semiconductor package of claim 5, wherein the plurality of through-grooves comprises first, second, third, and fourth through-grooves that are disposed in a trench shape along four respective side surfaces of the semiconductor chip, and
wherein the first, second, third, and fourth through-grooves are spaced apart from each other by a predetermined distance in areas adjacent to four corner portions of the semiconductor chip.

7. The fan-out semiconductor package of claim 1, wherein the frame comprises a plurality of wiring layers electrically connected to each other,
the recess portion is provided with a stopper layer, the stopper layer being disposed on a bottom surface of the recess portion on a same level as one of the plurality of wiring layers and including a metal material, and
the semiconductor chip is disposed with the inactive surface facing the stopper layer.

8. The fan-out semiconductor package of claim 7, wherein at least one of the plurality of wiring layers comprises a signal pattern, and
the metal layer is electrically insulated from the signal pattern.

9. The fan-out semiconductor package of claim 8, wherein at least one of the plurality of wiring layers comprises a ground pattern, and
the metal layer is electrically connected to the ground pattern.

10. The fan-out semiconductor package of claim 7, further comprising:
a first connection member electrically connecting the connection pad to the redistribution layer; and
a second connection member electrically connecting the plurality of wiring layers of the frame to the redistribution layer,
wherein the encapsulant covers a respective side surface of each of the first and second connection members.

11. The fan-out semiconductor package of claim 10, wherein a surface of each of the first and second connection members in contact with the connection structure, and a surface of the encapsulant in contact with the connection structure, are coplanar with each other.

12. The fan-out semiconductor package of claim 11, wherein the connection structure comprises:
an insulating layer disposed on a surface coplanar with the coplanar surfaces of the first and second connection members and the encapsulant,
first and second connection vias passing through the insulating layer and in contact with the first and second connection members, respectively, and
the redistribution layer disposed on the insulating layer and electrically connected to the first and second connection members via the first and second connection vias.

13. The fan-out semiconductor package of claim 1, wherein the frame comprises a core insulating layer, first and second wiring layers disposed on opposing surfaces of the core insulating layer, respectively, a first wiring via layer penetrating through the core insulating layer and electrically connecting the first and second wiring layers to each other, a first build-up insulating layer and a second build-up insulating layer disposed on the opposing surfaces of the core insulating layer and covering the first and second wiring layers, respectively, a third wiring layer disposed on the first build-up insulating layer, a second wiring via layer penetrating through the first build-up insulating layer and electrically connecting the first and third wiring layers, a fourth wiring layer disposed on the second build-up insulating layer, and a third wiring via layer penetrating through the second build-up insulating layer and electrically connecting the second and fourth wiring layers to each other,
wherein the one or more through-grooves each penetrate through the core insulating layer, and
wherein at least one of the first and second build-up insulating layers extends into and fills at least a portion of each of the one or more through-grooves.

14. The fan-out semiconductor package of claim 13, wherein the recess portion has a bottom surface on which a stopper layer including a metal material is disposed,
wherein the stopper layer is disposed on a surface of the core insulating layer to be parallel with the first wiring layer,
wherein the semiconductor chip is disposed in such a manner that the inactive surface faces the stopper layer, and
wherein the third wiring layer is disposed on a level different from the stopper layer.

15. A fan-out semiconductor package comprising:
a frame having a recess portion, the frame including first and second wiring layers disposed on different levels, one or more wiring vias electrically connecting the first and second wiring layers to each other, and one or more shielding members disposed around the recess portion and each extending in a respective direction along a periphery of the recess portion;
a semiconductor chip having a connection pad and disposed in the recess portion;
an encapsulant covering at least a portion of each of the frame and the semiconductor chip, and filling at least a portion of the recess portion; and
a connection structure disposed on the frame and the semiconductor chip, and including a redistribution layer electrically connected to the first and second wiring layers and the connection pad,
wherein the one or more wiring vias each have a form in which a respective through-hole penetrating through at least a portion of the frame is filled with a metal material, and
each of the one or more shielding members has a form in which a metal material is disposed conformally in a respective through-groove penetrating through at least a portion of the frame in the form of a trench.

16. The fan-out semiconductor package of claim 15, wherein a bottom surface of the recess portion is provided with a stopper layer including a metal material.

17. A fan-out semiconductor package comprising:
a frame having a recess portion;
a semiconductor chip disposed in the recess portion;
a plurality of through-grooves each penetrating through at least a portion of the frame, and disposed around the recess portion such that the through-grooves extend along each respective side surface of the recess portion and each has a length longer than the respective side surface;
a plurality of metal layers each disposed on side walls of a respective through-groove of the plurality of through-grooves; and
an encapsulant covering at least a portion of each of the frame and the semiconductor chip and filling at least a portion of the recess portion.

18. The fan-out semiconductor package of claim 17, wherein each metal layer is disposed on opposing side walls of the respective through-groove, and a space disposed between the metal layer disposed on the opposing side walls is filled with an insulating material.

19. The fan-out semiconductor package of claim 17, wherein the plurality of through-grooves are spaced apart from each other at locations adjacent to corners of the recess portion, and the frame extends between adjacent through-grooves at the locations adjacent to corners of the recess portion.

20. The fan-out semiconductor package of claim 17, wherein the frame comprises first and second wiring layers disposed on opposing surfaces of a core insulating layer and connected to each other by one or more connection vias,
each through-groove of the plurality of through-grooves extends through the core insulating layer from one to another of the opposing surfaces of the core insulating layer, and
the recess portion extends through the core insulating layer to a stopper layer disposed coplanar with the first wiring layer.
